(19) United States
(12) Patent Application Publication
(10) Pub. No.: US 2003/0022513 A1
(43) Pub. Date: Jan. 30, 2003

(54) Polymer debris pre-cleaning method

(76) Inventors: Yann-Pyng Wu, Miao-Li Hsien (TW); Yueh-Feng Ho, Hsinchu (TW); Gow-Wei Sun, Taipei Hsien (TW); Jen-Ku Hung, Tainan (TW)

Correspondence Address: J.C. Patents, Inc., Suite 250, 4 Venture, Irvine, CA, 92618, US

(21) Appl. No.: 10/200,268

(22) Filed: Jul. 19, 2002

(30) Foreign Application Priority Data
Jul. 24, 2001 (TW) 90118011

(51) Int. Cl. H01L 21/302; H01L 21/461

(52) U.S. Cl. 438/710

(57) ABSTRACT

A polymer debris pre-cleaning method is described. The method provides a specific gas mixture after an etching process that uses a fluorocarbon reacting gas. The plasma generated from the gas mixture is then used to perform a pre-cleaning of the polymer debris. The gas mixture of specific gases is selected from the group of an oxygen and nitrogen gas mixture, a hydrogen and argon gas mixture, an argon and nitrogen gas mixture, or an oxygen and argon gas mixture. Since the plasma generated from the gas mixture softens, burns or even removes the hardened polymer debris, the polymer debris can be completely removed in the subsequent cleaning process. The duration of the subsequent cleaning process is thus reduced.

### CROSS REFERENCE TO RELATED APPLICATION

This application claims the priority benefit of Taiwan application serial no. 90118011, filed on Jul. 24, 2001.

### BACKGROUND OF THE INVENTION

1. Field of Invention

The present invention relates to a method for cleaning debris in semiconductor processing. More particularly, the present invention relates to a method for pre-cleaning polymer debris.

2. Description of Related Art

Dry etching is an etching technique that bases on the principle of particle bombardment to perform thin film etching. Plasma etching is a type of dry etching, wherein the reacting gas molecule is ionized by plasma to form ions that are reactive with the thin film material. The thin film, after being exposed to plasma, is converted to a volatile product due to the chemical interaction between the ions and the thin film. The volatile product is then removed to complete the etching process. This type of etching method, although, can provide selectivity, its anisotropic characteristic is less satisfactory. In order for a dry etching method to provide the characteristics of high selectivity and anisotropism, reactive ion etching is developed.

Reactive etching is a type of dry etching technique that combines plasma etching and sputtering etching principles, wherein a thin film is removed by both physical and chemical mechanisms. An anisotropic etching with a high selectivity is thereby resulted. RIE is applicable in the manufacturing for a via, a contact, a dual damascene, etc. Moreover, RIE can be applied in the removal of a stop layer used in the etching of a via and a trench in a via, contact or dual damascene manufacturing process.

Plasma used in reactive ion etching is often generated from a fluorocarbon gas, which includes carbon tetrafluoride (CF₄). C₄F₈, C₅F₈ or C₄F₆ are also being used as reacting gas to provide carbon atoms and fluorine atoms. However, the removal of the polymer debris after the completion of the etching process is an essential step. If the etching recipe, which includes polymer such as C₄F₈, C₅F₈ or C₄F₆, is used to perform the etching, polymer debris, composed of carbon, fluorine, nitrogen and oxygen elements, is formed when the etching process is completed. The removal of the polymer debris would become a challenge and a burden in the subsequent polymer and photoresist cleaning process. In general, the aforementioned polymer debris is difficult to remove by the typical polymer and photoresist cleaning process. Moreover, this type of polymer debris would introduce complication in the via, contact or dual damascene manufacturing process, leading to a low yield.

Normally, a polymer debris cleaning process is performed after an etching process is conducted that uses a fluorocarbon plasma. However, even after the conventional polymer debris cleaning process, polymer debris is still remaining on the substrate. Additionally, the polymer debris is hardened polymer, and can not be removed even after a repeated wet clean with solvent.

### SUMMARY OF THE INVENTION

The present invention provides a polymer debris pre-cleaning method, wherein the polymer debris resulted from an etching process is softened, burnt and even removed. The processing time is thus reduced to provide a consistent yield.

The present invention provides a polymer cleaning method, wherein the polymer debris resulted from an etching process is completely removed. The processing time is thus reduced and the yield is maintained.

The present invention provides a polymer debris pre-cleaning method. The method is applicable after an etching process that uses a fluorocarbon containing gas as reacting gas. A specific gas mixture is introduce to generate plasma to perform the pre-cleaning process, wherein the specific gas mixture is selected from the group consisting of an oxygen and nitrogen gas mixture, a hydrogen and argon gas mixture, an argon and oxygen gas mixture and an oxygen and argon gas mixture. Since the plasma generated from the specific gas mixture can soften, burn and even remove the hardened polymer debris, the polymer debris is completely removed in the subsequent cleaning process. The duration of the subsequent cleaning process is thereby reduced.

Additionally, the present invention provides a polymer debris cleaning method, wherein a specific gas mixture is introduced in the dechuck step of an etching process. The plasma generated from the specific gas mixture is used to perform a pre-cleaning process, wherein the gas mixture is selected from the group consisting of an oxygen and nitrogen gas mixture, a hydrogen and argon gas mixture, an argon and oxygen gas mixture and an oxygen and argon gas mixture. A cleaning process is further conducted to completely remove the polymer debris.

Furthermore, the present invention provides a polymer debris cleaning method, wherein a specific gas mixture is introduced in an etching process. The plasma generated from the specific gas mixture is used to perform a pre-cleaning process, wherein the gas mixture is selected from the group consisting of an oxygen and nitrogen gas mixture, a hydrogen and argon gas mixture, an argon and oxygen gas mixture and an oxygen and argon gas mixture. A cleaning process is further conducted to completely remove the polymer debris.

According to a first preferred embodiment of the present invention, which is applicable in the etching process for forming a via, a contact or a dual damascene. A specific gas mixture of oxygen and nitrogen, hydrogen and argon, argon and oxygen, or oxygen and argon is introduced and replaces the original argon gas during the dechuck process. The plasma generated from the gas mixture is used to pre-clean the polymer debris, wherein the pre-cleaning process only requires 5 seconds. Thereafter, a cleaning process is performed to completely remove the hardened polymer debris. The present invention not only completely removes the polymer debris, the processing time is not increased to maintain the yield.

According to a second preferred embodiment of the present invention, which is applicable to the etching of a stop layer during the manufacturing of a via, a contact or a dual damascene. A specific gas mixture of oxygen and nitrogen, hydrogen and argon, argon and oxygen, or oxygen and argon is introduced and replaces the original argon gas. The plasma generated from the gas mixture is used to pre-clean the polymer debris. Subsequent to the removal of the stop layer, a cleaning process is performed to completely remove the hardened polymer debris. Since the pre-clean process reduces or completely removes the polymer debris, the subsequent cleaning process can be eliminated or shortened. Moreover, the cleaning chamber of the subsequent cleaning process is thus not adversely affected to thereby maintain the yield and to reduce the production time.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow diagram showing the processing steps for cleaning polymer debris according to a preferred embodiment of the present invention.

FIG. 2 is a flow diagram showing the processing steps for cleaning polymer debris according to another preferred embodiment of the present invention.

FIGS. 3A and 3B are schematic, cross-sectional views showing a dual damascene manufacturing process of a via opening and a trench.

### DESCRIPTION OF THE PREFERRED EMBODIMENTS

### First Embodiment

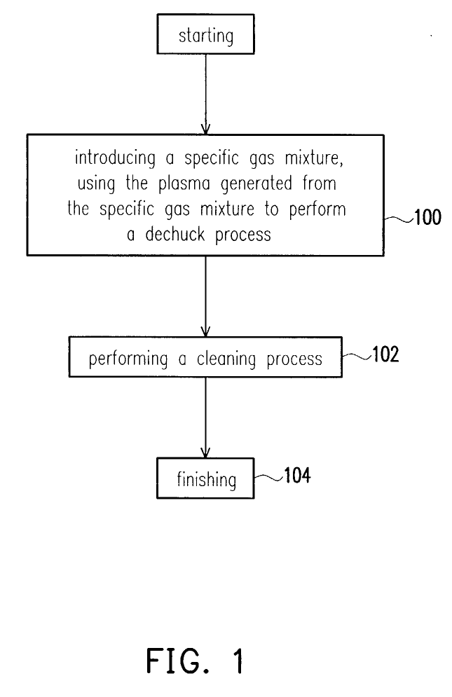

FIG. 1 is a flow diagram showing the processing steps for cleaning polymer debris according to a preferred embodiment of the present invention. The process for cleaning polymer debris of the present invention is applicable to an etching process for forming an opening in a dielectric layer, wherein the dielectric layer includes a silicon oxide dielectric layer and the opening formed in the dielectric layer includes a metal via (MVIA) opening, a contact opening and a dual damascene opening, etc. The type of etcher used for the preferred embodiment is known as the magnetic-enhanced reactive ion etcher (MERIE).

The reaction gas used in the conventional etching process includes fluorocarbon gas, such as C₄F₈, C₅F₈ or C₄F₆. Static electricity is formed on the wafer surface subsequent to the etching process being performed in a MERIE etcher because of the non-uniform accumulation of electrons resulted from an uni-directional magnetic field. A dechuck step is thus conducted. Moreover, the polymer debris that is formed with carbon, fluorine, nitrogen and oxygen types of elements generated in the etching process are difficult to clean off from the wafer.

As shown in FIG. 1, a specific mixture of gas is delivered to the etcher in step 100. A dechuck removal process is conducted using the plasma generated from the gas mixture, wherein a pre-cleaning process of the polymer debris is concurrently performed. The specific gas mixture includes, for example, oxygen and nitrogen (O₂+N₂), hydrogen and argon (H₂+Ar), argon and nitrogen (Ar+N₂) or oxygen and argon (O₂+Ar) type of gas mixture. The oxygen and nitrogen gas mixture is especially more applicable for this preferred embodiment, wherein the mixture ratio (in terms of nitrogen flow rate/oxygen flow rate) is between 2 to 0.5. If the nitrogen flow rate is x sccm, the oxygen flow rate is y and x+y is between 50 to 200, the static electricity removal process is accomplished in about 5 seconds.

The plasma generated from the O₂+N₂ gas mixture not only removes the electrical charge that is accumulated on the wafer surface, the nitrogen gas can soften the polymer debris and the oxygen gas can burn the polymer debris. The hardened polymer, therefore, is more easily removed in step 102 after the dechuck process.

Thereafter, a cleaning process is conducted in step 102. The cleaning process includes the regular cleaning process, such as, ashing or wet cleaning, which is used to remove polymer and photoresist type of material. Subsequently, step 104 is performed to complete the polymer debris cleaning process.

Replacing argon gas by the plasma generated by the specific gas mixture to perform the dechuck process, the hardened polymer debris is softened, burnt and even removed. The hardened polymer debris is thus completely removed in the subsequent cleaning process. The present invention not only can provide a method to completely remove the polymer debris resulted from the etching process, the cleaning process does not need to be lengthened to maintain the yield.

### Second Embodiment

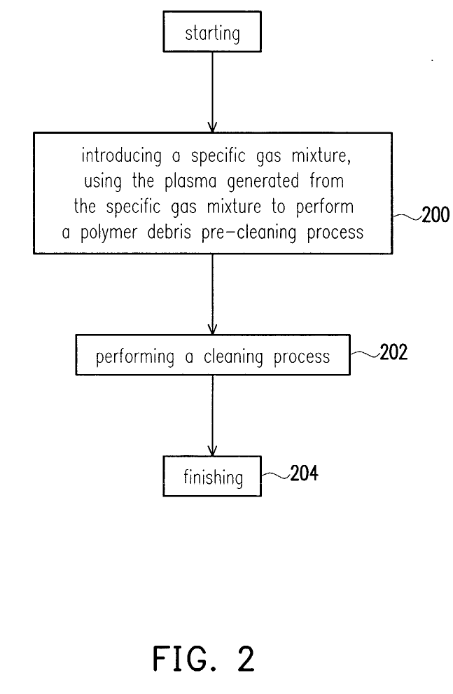

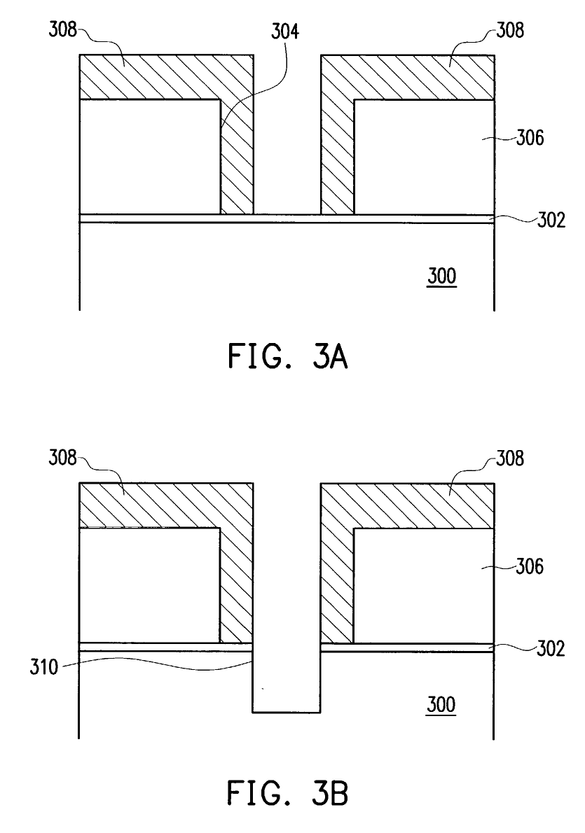

FIG. 2 is a flow diagram showing the processing steps for cleaning polymer debris according to another preferred embodiment of the present invention. The method in cleaning polymer debris according to the second preferred embodiment is applicable to the removal process of a stop layer, wherein the stop layer includes the stop layer used in the etching of a self-aligned contact, a borderless contact, a dual damascene, etc in a dielectric layer. The stop layer includes silicon nitride, silicon carbon or silicon oxynitride. To properly illustrate the position of the stop layer, the etching of the stop layer in forming a via opening in a dual damascene process is used as an example. FIGS. 3A and 3B are schematic, cross-sectional views showing the manufacturing of a via opening and a trench in a dual damascene process.

As shown in FIG. 3A, a substrate 300, comprising a stop layer 302 formed thereon, is provided. A dielectric layer 306 having a trench 304 formed therein is formed on the stop layer 302. A patterned photoresist layer 308 is formed on the substrate 300, exposing the stop layer 302.

Continue to FIG. 3B, using the photoresist layer 308 as a mask, etching is conducted to remove the exposed stop layer 302 and a portion of the substrate 300 to form a via opening 310.

During the removal of the stop layer in between dielectric layers or in between a dielectric layer and a metal layer, a fluorocarbon reacting gas is normally used for the etching of the stop layer. The fluorocarbon reacting gas includes C₄F₈, C₅F₈ or C₄F₆. The polymer debris that is formed with carbon, fluorine, nitrogen and oxygen types of elements generated in the etching process are difficult to clean from the wafer.

As a result, as shown in FIG. 2, a mixture of specific gases is delivered to the etcher in step 200, using the plasma generated from the gas mixture to perform the polymer debris cleaning process, wherein the gas mixture includes, for example, oxygen and nitrogen (O₂+N₂), hydrogen and argon (H₂+Ar), argon and nitrogen (Ar+N₂) or oxygen and argon (O₂+Ar) type of gas mixture. The nitrogen gas flow rate in the gas mixture is between 1 to 1000 sccm, the oxygen gas flow rate in the gas mixture is between 1 to 1000 sccm, the argon gas flow rate is between about 1 to 1000 sccm and the hydrogen gas flow rate is between about 1 to 1000 sccm. Using the oxygen gas and nitrogen gas mixture to perform the treatment process, the ratio of nitrogen gas to oxygen gas, in terms of flow rate, is between 2 to 0.5. When the plasma formed with the specific gas mixture is introduced in step 200 to remove the polymer debris, the subsequent cleaning process 202 can be substantially shortened.

The cleaning process 202 includes the typical cleaning process for removing polymer and photoresist type of material. Step 204 is further performed to complete the polymer debris cleaning process.

Accordingly, the plasma generated from the gas mixture used in the polymer debris pre-cleaning process can clean the hardened polymer debris. The present invention not only provides the advantage of completely removing the polymer debris resulted from an etching process, the subsequent cleaning process is shortened due to a reduction or a removal of the polymer debris in the previous pre-cleaning process. The yield is thus maintained and the production time is reduced.

In summary, the present invention provides a pre-cleaning method that uses oxygen and nitrogen, hydrogen and argon, argon and nitrogen or oxygen and argon type of gas mixture to clean the polymer debris subsequent to an etching process that uses fluorocarbon gas source. The polymer debris formed during the etching process is easily removed in the subsequent cleaning process to shorten the manufacturing time and to increase the yield.

Based on the foregoing, no addition step is required for the complete removal of the polymer debris formed during the etching of an opening. Additionally, the plasma generated by the special gas mixture is used in cleaning the polymer debris when the stop layer is removed in between the dielectric layers or in between a dielectric layer and a metal layer. The subsequent cleaning process, such as ashing or wet clean, is greatly shortened. Moreover, the polymer debris resulted from an etching process can be completely removed according to the present invention. The yield is thus more consistent compared to the prior art.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A polymer debris pre-cleaning method, which is applicable in a cleaning of polymer debris resulted from an etching process that uses a fluorocarbon gas mixture as an etching gas, wherein the method includes a step of delivering a gas mixture and using plasma generated from the gas mixture to perform a polymer debris pre-cleaning process.

2. The method of claim 1, wherein the gas mixture includes an oxygen gas and a nitrogen gas.

3. The method of claim 1, wherein a ratio of a nitrogen gas flow rate and an oxygen gas flow rate is between 2 and 0.5.

4. The method of claim 2, wherein a total gas flow rate of the gas mixture is between 50 sccm and 200 sccm.

5. The method of claim 1, wherein the gas mixture includes a hydrogen gas and an argon gas.

6. The method of claim 5, wherein a hydrogen gas flow rate and an argon gas flow rate in the gas mixture is between 1 sccm and 1000 sccm, respectively.

7. The method of claim 1, wherein the gas mixture includes an argon gas and a nitrogen gas.

8. The method of claim 7, wherein a nitrogen gas flow rate and an argon gas flow rate in the gas mixture is between 1 sccm and 1000 sccm, respectively.

9. The method of claim 1, wherein the gas mixture includes an oxygen gas and an argon gas.

10. The method of claim 9, wherein an oxygen gas flow rate and an argon gas flow rate in the gas mixture is between 1 sccm and 1000 sccm, respectively.

11. A method for cleaning polymer debris, which is applicable in a cleaning of polymer debris resulted from an etching process that uses a fluorocarbon gas as a reacting gas to form an opening in a dielectric layer, the method comprising:
performing a dechuck process, wherein a gas mixture is provided for the dechuck process, and plasma generated from the gas mixture is used to concurrently perform a polymer debris pre-cleaning process; and
performing a cleaning process.

12. The method of claim 11, wherein the gas mixture includes an oxygen gas and a nitrogen gas.

13. The method of claim 12, wherein a ratio of a nitrogen gas flow rate and an oxygen gas flow rate in the gas mixture is between 2 to 0.5.

14. The method of claim 12, wherein the a total gas flow rate for the gas mixture is between 50 sccm and 200 sccm.

15. The method of claim 11, wherein the gas mixture includes a hydrogen gas and an argon gas.

16. The method of claim 11, wherein the gas mixture includes a nitrogen gas and an argon gas.

17. The method of claim 11, wherein the gas mixture includes an oxygen gas and an argon gas.

18. The method of claim 11, wherein performing the cleaning process includes performing ashing and wet cleaning.

19. A polymer debris cleaning method, which is applicable in cleaning polymer debris after an etching process, wherein the etching process uses a fluorocarbon gas mixture as a reacting gas to remove a stop layer, comprising:
providing a gas mixture and using plasma generated from the gas mixture to perform a polymer debris pre-cleaning process; and
performing a cleaning process.

20. The method of claim 19, wherein the gas mixture includes an oxygen gas and a nitrogen gas.

21. The method of claim 20, wherein a ratio of a nitrogen gas flow rate and an oxygen gas flow rate of the gas mixture is between 2 to 0.5.

22. The method of claim 20, wherein a total gas flow rate of the gas mixture is between 50 sccm to 200 sccm.

23. The method of claim 19, wherein the gas mixture includes a hydrogen gas and an argon gas.

24. The method of claim 23, wherein a hydrogen gas flow rate and an argon gas flow rate in the gas mixture is between 1 sccm and 1000 sccm, respectively.

25. The method of claim 19, wherein the gas mixture includes an argon gas and a nitrogen gas.

26. The method of claim 25, wherein an argon gas flow rate and a nitrogen gas flow rate in the gas mixture is between 1 sccm and 1000 sccm, respectively.

27. The method of claim 19, wherein the gas mixture includes an oxygen gas and an argon gas.

28. The method of claim 27, wherein an oxygen gas flow rate and an argon gas flow rate in the gas mixture is between 1 sccm and 1000 sccm, respectively.

29. The method of claim 19, wherein performing the cleaning process includes performing ashing or wet clean.

30. The method of claim 19, wherein the stop layer includes a stop layer used in an etching of a dielectric layer in a self-aligned contact process.

31. The method of claim 19, wherein the stop layer includes a stop layer used in an etching of a dielectric layer in a borderless contact process.

32. The method of claim 19, wherein the stop layer includes a stop layer used in an etching of a dielectric layer in a dual damascene process.

33. The method of claim 19, wherein the stop layer includes silicon nitride, silicon oxy-nitride or silicon carbon.
